(19) United States
(12) Patent Application Publication
(10) Pub. No.: US 2011/0203921 A1
(43) Pub. Date: Aug. 25, 2011

(54) METHOD OF BONDING ROTATABLE CERAMIC TARGETS TO A BACKING STRUCTURE

(75) Inventor: Eugene Y. Ivanov, Grove City, OH (US)

(73) Assignee: TOSOH SMD, INC., Grove City, OH (US)

(21) Appl. No.: 13/029,823

(22) Filed: Feb. 17, 2011

Related U.S. Application Data
(60) Provisional application No. 61/338,538, filed on Feb. 19, 2010.

(51) Int. Cl. C23C 14/35; C23C 14/08; B23P 11/00

(52) U.S. Cl. 204/298.13; 204/298.12; 29/428

(57) ABSTRACT

This invention relates to a rotatable cylindrical magnetron sputtering apparatus and related process. More specifically, the invention relates to a cylindrical target assembly for a cylindrical magnetron sputtering device which includes a target portion where the target portion is metal, metal oxide, or ceramic and is not bonded to any backing tube. Instead, the cylindrical target is resiliently, yet fixedly mounted to the backing tube by a multiplicity of resilient, yieldable contacts. The assembly allows the target portion to heat up uniformly and expand, thereby allowing the cylindrical magnetron to operate at increased power levels.

### RELATED APPLICATION

This application claims the priority filing benefit of U.S. Provisional Patent Application Ser. No. 61/338,538, filed Feb. 19, 2010, and entitled “Method of bonding rotatable ceramic targets to a backing structure”, which is incorporated by reference herein in its entirety.

### BACKGROUND OF THE INVENTION

1. Field of the Invention

This invention relates to a rotatable cylindrical magnetron sputtering apparatus and related process. More specifically, the invention relates to a cylindrical target assembly for a cylindrical magnetron sputtering device which includes a target portion where the target portion is metal, metal oxide, or ceramic and is not bonded to any backing tube.

2. Description of Related Art

A typical magnetron sputtering device includes a vacuum chamber having an electrode contained therein, wherein the electrode includes a cathode portion, an anode portion and a target. The term electrode is oftentimes referred to in the industry as a cathode. In operation, a vacuum is drawn in the vacuum chamber followed by the introduction of a process gas into the chamber. Electrical power supplied to the electrode produces an electronic discharge, which ionizes the process gas and produces charged gaseous ions from the atoms of the process gas. The ions are accelerated and retained within a magnetic field formed over the target and are propelled toward the surface of the target which is composed of the material sought to be deposited on a substrate. Upon striking the target, the ions dislodge target atoms from the target, which are then deposited upon the substrate. By varying the composition of the target and/or the process gas, a wide variety of substances can be deposited on various substrates. The result is the formation of an ultra-pure thin film deposition of target material on the substrate.

Over the last decade, the cylindrical magnetron has emerged as a leading technology for sputter coating on both rigid and flexible substrates. A rotating cylindrical target surface provides for a constant sputtering surface, thus minimizing the traditional erosion groove and large non-sputtered areas associated with planar targets. Further, a cylindrical target eliminates large areas of dielectric buildup that can lead to arcing, material flaking, debris, and other process instabilities.

Transparent conductive coatings are used in a broad variety of devices, which may include Plasma, TFT, or LCD televisions, and computer monitors to solar cells, to resistive heating windshields for aircraft and trains, with a broad variety of applications in between. Typically, these transparent conductive coatings are made of indium tin oxide (ITO) or aluminum zinc oxide (AZO) thin films. Further, the majority of these devices have the transparent conductive coatings applied by sputter deposition.

One method of applying ITO and AZO films, in order to obtain the best electrical conductivity and visual transparency, is to apply the coatings to substrates at elevated temperatures, specifically above 200° C. The problem is that the films can be optically reflective in the infrared spectrum, and therefore, as the film grows in thickness, it becomes necessary to continually apply more heat in order to maintain this temperature for the duration of the coating cycle.

Some problems associated with sputtering these ITO or AZO targets are target cracking and the formation of nodules. When a target cracks, there is an increased opportunity for the generation of particulate contamination, as well as arcing on the surface of the target, thereby causing production yield loss. Nodules are known to be sites of impurities which form on the target surface and which may involve inhibiting the quality of the film formation, as well as slowing down the deposition rate, thereby causing yield loss and throughput.

Accordingly, there is a need for a rotatable sputter target assembly having a design which reduces instances of target cracking and the formation of nodules.

SUMMARY OF INVENTIVE FEATURES

In one aspect of the invention, a rotatable sputter target assembly is comprised of a cylindrical target concentrically mounted over a cylindrical backing tube, the cylindrical target has an inner surface and the cylindrical backing tube has an outer surface. A backing material is located between the cylindrical target and the cylindrical backing tube.

In another aspect of the sputter target assembly, the backing material resiliently connects the cylindrical target and the cylindrical backing tube along a multitude of support locations on the inner surface of the target.

In another aspect of the sputter target assembly, the backing material is corrugated sheet metal or mesh metal.

In another aspect of the sputter target assembly, the cylindrical target is comprised of a ceramic or metal oxide material. In another aspect of the sputter target assembly, the cylindrical target is comprised of at least one of indium tin oxide (ITO) or aluminum zinc oxide (AZO).

In another aspect of the sputter target assembly, the cylindrical backing tube is comprised of at least one of Al, Al alloy, stainless steel, copper, or titanium.

In another aspect of the sputter target assembly, a mechanical fastener connects the backing material to the cylindrical target and the cylindrical backing tube.

In another aspect of the sputter target assembly, a chemical fastener connects the backing material to the cylindrical target and the cylindrical backing tube.

In another aspect of the sputter target assembly, the backing material is secured to the cylindrical target and the cylindrical backing tube by friction.

In another aspect of the sputter target assembly, the corrugated sheet metal is comprised of inner ridges and outer ridges; the outer ridges contact the inner surface of the cylindrical target and the inner ridges contact the outer surface of the cylindrical backing tube.

In another aspect of the sputter target assembly, the mesh metal is comprised of outer wire and inner wire; the outer wire contacts the inner surface of the cylindrical target and the inner wire contacts the outer surface of the cylindrical backing tube.

In yet another aspect of the invention, a method of fabricating a rotatable sputter target assembly comprises the steps of: providing a cylindrical target, a cylindrical backing tube, and a backing material; the cylindrical backing tube further comprising an outer surface and the cylindrical target further comprising an inner surface; rolling the backing material onto the outer surface of the cylindrical backing tube; and fitting the cylindrical target on top of the backing material, wherein the cylindrical target and the cylindrical backing tube are concentric.

In another aspect of the method of fabricating a rotatable sputter target assembly, the backing material resiliently connects the cylindrical target and the cylindrical backing tube along a multitude of support locations on the inner surface of the target.

In another aspect of the method of fabricating a rotatable sputter target assembly, the backing material is corrugated sheet metal or mesh metal. In another aspect of the method of fabricating a rotatable sputter target assembly, the cylindrical target is comprised of a ceramic or metal oxide material. In another aspect of the method of fabricating a rotatable sputter target assembly, the cylindrical target is comprised of at least one of indium tin oxide (ITO) or aluminum zinc oxide (AZO). In another aspect of the method of fabricating a rotatable sputter target assembly, the cylindrical backing tube is comprised of at least one of Al, Al alloy, stainless steel, copper, or titanium.

In yet another aspect of the invention, a method of fabricating a rotatable sputter target assembly comprises the steps of: providing a cylindrical target and a cylindrical backing tube; the cylindrical backing tube further comprising an outer surface and the cylindrical target further comprising an inner surface; and resiliently connecting the cylindrical target and the cylindrical backing tube along a multitude of support locations on the inner surface of the target, wherein the cylindrical target and the cylindrical backing tube are concentric.

In another aspect of the method of fabricating a rotatable sputter target assembly, a backing material resiliently connects the cylindrical target and the cylindrical backing tube along a multitude of support locations on the inner surface of the target.

In another aspect of the method of fabricating a rotatable sputter target assembly, the backing material is corrugated sheet metal or mesh metal.

Advantages of the present invention will become more apparent to those skilled in the art from the following description of the embodiments of the invention which have been shown and described by way of illustration. As will be realized, the invention is capable of other and different embodiments, and its details are capable of modification in various respects.

### BRIEF DESCRIPTION OF THE DRAWINGS

These and other features of the present invention, and their advantages, are illustrated specifically in embodiments of the invention now to be described, by way of example, with reference to the accompanying diagrammatic drawings, in which:

FIG. 1 illustrates an embodiment of the sputter target assembly in accordance with the present invention;

FIG. 1A illustrates a cross section of an embodiment of the sputter target assembly in accordance with the present invention;

FIG. 2 illustrates a cross section of an embodiment of the sputter target assembly in accordance with the present invention; and

FIG. 3 illustrates a cross section of an embodiment of the sputter target assembly in accordance with the present invention.

It should be noted that all the drawings are diagrammatic and not drawn to scale. Relative dimensions and proportions of parts of these figures have been shown exaggerated or reduced in size for the sake of clarity and convenience in the drawings. The same reference numbers are generally used to refer to corresponding or similar features in the different embodiments. Accordingly, the drawing(s) and description are to be regarded as illustrative in nature and not as restrictive.

### DETAILED DESCRIPTION OF THE INVENTION

Approximating language, as used herein throughout the specification and claims, may be applied to modify any quantitative representation that could permissibly vary without resulting in a change in the basic function to which it is related. Accordingly, a value modified by a term or terms, such as “about”, is not limited to the precise value specified. In at least some instances, the approximating language may correspond to the precision of an instrument for measuring the value. Range limitations may be combined and/or interchanged, and such ranges are identified and include all the sub-ranges stated herein unless context or language indicates otherwise. Other than in the operating examples or where otherwise indicated, all numbers or expressions referring to quantities of ingredients, reaction conditions and the like, used in the specification and the claims, are to be understood as modified in all instances by the term “about”.

“Optional” or “optionally” means that the subsequently described event or circumstance may or may not occur, or that the subsequently identified material may or may not be present, and that the description includes instances where the event or circumstance occurs or where the material is present, and instances where the event or circumstance does not occur or the material is not present.

As used herein, the terms “comprises”, “comprising”, “includes”, “including”, “has”, “having”, or any other variation thereof, are intended to cover a non-exclusive inclusion. For example, a process, method, article or apparatus that comprises a list of elements is not necessarily limited to only those elements, but may include other elements not expressly listed or inherent to such process, method, article, or apparatus.

The singular forms “a”, “an”, and “the” include plural referents unless the context clearly dictates otherwise.

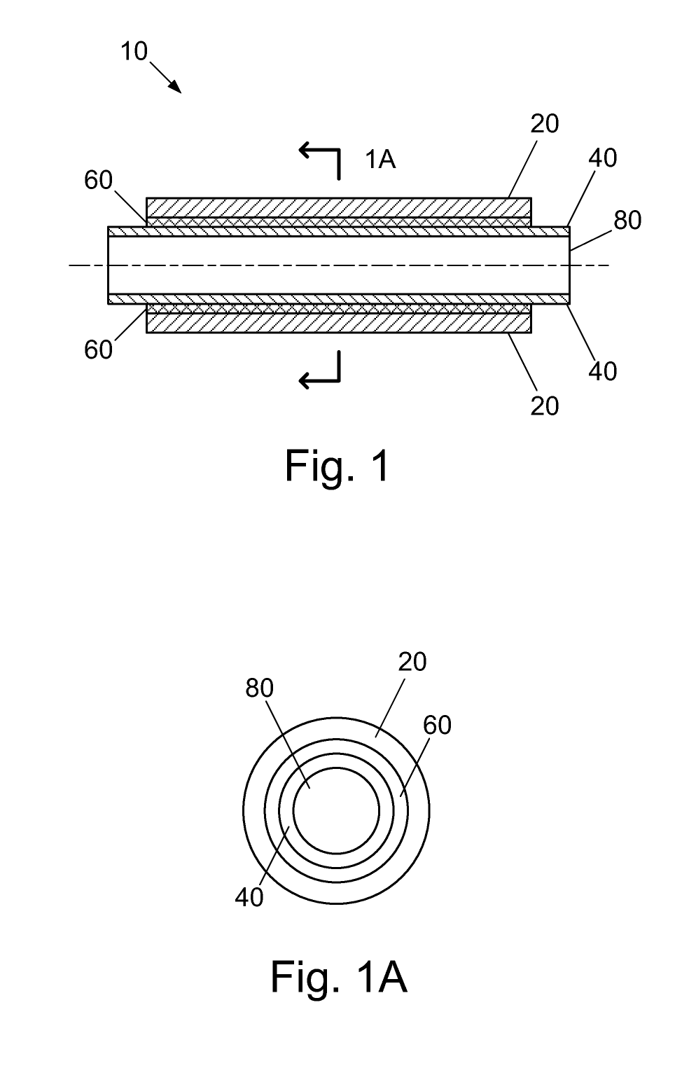

Turning to the drawings, FIGS. 1 and 1A show rotatable sputter target assembly 10 comprising cylindrical target 20 concentrically mounted over cylindrical backing tube 40. The target 20 and backing tube 40 are adapted for rotation around a central axis 80 of the assembly. Means for imparting the desired rotation can be seen for example in U.S. Pat. Nos. 5,262,032 and 5,464,518, both of which are herein incorporated by reference. A backing material 60 is located between the inner surface 22 of target 20 and the outer surface 41 of backing tube 40.

In accordance with one embodiment of the invention, target 20 may be comprised of a ceramic or metal oxide material, such as indium tin oxide (TTO) or aluminum zinc oxide (AZO). The backing tube 40 may be comprised of Al, Al alloy, stainless steel, copper, titanium, or any other material deemed suitable by a person having ordinary skill in the art.

As shown in the drawings, a backing material 60 occupies the annular space between the target 20 and backing tube 40. In some embodiments backing material 60 is corrugated sheet metal. In other embodiments, backing material 60 is mesh metal. Backing material 60 resiliently connects the target 20 and backing tube 40 along a multitude of support locations on the inner surface 22 of the target 20. Backing material 60 could be connected to the target 20 and backing tube 40 by a mechanical or chemical fastener. Alternatively, backing material 60 could be secured to the target 20 and backing tube 40 only by friction, such as through a friction fit.

Accordingly, in one embodiment, this invention utilizes a backing material 60 that is rolled around backing tube 40. The cylindrical, rotatable ceramic target 20 is then fitted on top of the backing material 60. Backing material 60 functions like multiple springs so as to provide a resilient, fixed mount of the target 20 to the backing tube 40. Resiliently connecting the target 20 and backing tube 40 along a multitude of support locations prevents the formation of concentrated heat areas in the target 20. Thereby reducing the likelihood of crack and nodule formation in or on target 20.

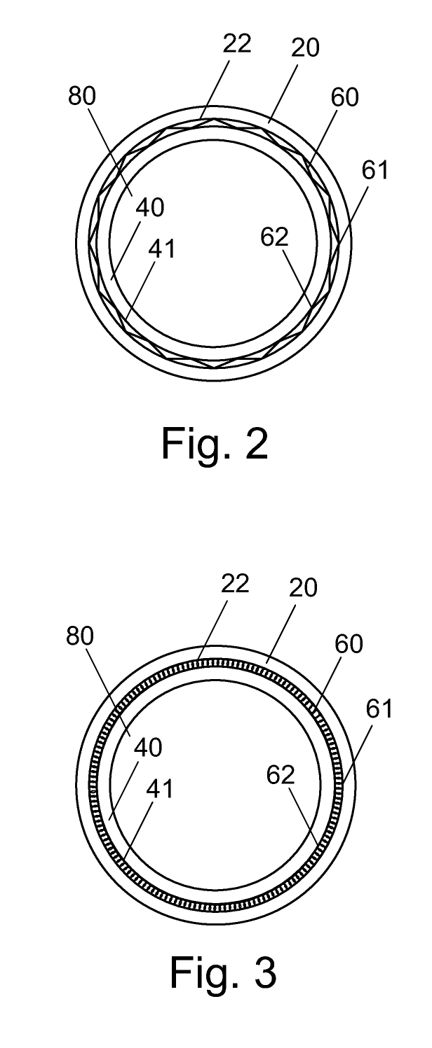

FIG. 2 shows a cross section taken at 1A of FIG. 1 of an embodiment of the invention which utilizes corrugated sheet metal 60 rolled around the backing tube 40. The cylindrical, rotatable ceramic target 20 is fitted on top of the corrugated sheet metal 60. The outer ridges 61 of corrugated sheet metal 60 contact the inner surface 22 of target 20, and the inner ridges 62 of corrugated sheet metal 60 contact the outer surface 41 of backing tube 40. In some embodiments, ridges 61 and 62 run parallel to the central axis 80 of the sputter target assembly 10. In other embodiments, ridges 61 and 62 run perpendicular to the central axis 80 of the sputter target assembly 10. In additional embodiments, ridges 61 and 62 run both perpendicular and parallel to the central axis 80 of the sputter target assembly (e.g., a crisscross pattern). In additional embodiments, ridges 61 and 62 run neither parallel nor perpendicular to the central axis 80 of the sputter target assembly.

In some embodiments, ridges 61 and 62 run parallel with respect to each other. In other embodiments, ridges 61 and 62 run perpendicular with respect to each other. In additional embodiments, ridges 61 and 62 run both perpendicular and parallel with respect to each other (e.g., a crisscross pattern). In some embodiments, ridges 61 and 62 form an obtuse angle with respect to each other. In other embodiments, ridges 61 and 62 form a reflex angle with respect to each other. In other embodiments, ridges 61 and 62 form an acute angle with respect to each other.

The inner ridges 62 and outer ridges 61 of the corrugated metal 60 functions like multiple springs so as to provide a resilient, fixed mount of the target 20 to the backing tube 40. Resiliently connecting the target 20 and backing tube 40 along a multitude of support locations prevents the formation of concentrated heat areas in the target 20. Thereby reducing the likelihood of crack and nodule formation in or on target 20.

FIG. 3 shows a cross section taken at 1A of FIG. 1 of an embodiment of the invention which utilizes mesh metal 60 rolled around the backing tube 40. The cylindrical, rotatable ceramic target 20 is fitted on top of the mesh metal 60. The outer wire 61 of mesh metal 60 contact the inner surface 22 of target 20 and the inner wire 62 of mesh metal 60 contact the outer surface 41 of backing tube 40. In some embodiments, wires 61 and 62 run perpendicular to the central axis 80 of the sputter target assembly 10. In additional embodiments, wires 61 and 62 run both perpendicular and parallel to the central axis 80 of the sputter target assembly (e.g., a crisscross pattern). In additional embodiments, wires 61 and 62 run neither parallel nor perpendicular to the central axis 80 of the sputter target assembly.

In some embodiments, wires 61 and 62 run perpendicular with respect to each other. In additional embodiments, wires 61 and 62 run both perpendicular and parallel with respect to each other (e.g., a crisscross pattern). In some embodiments, wires 61 and 62 form an obtuse angle with respect to each other. In other embodiments, wires 61 and 62 form a reflex angle with respect to each other. In other embodiments, wires 61 and 62 form an acute angle with respect to each other.

The wires 62 and 61 of mesh metal 60 function like multiple springs so as to provide a resilient, fixed mount of the target 20 to the backing tube 40. Resiliently connecting the target 20 and backing tube 40 along a multitude of support locations prevents the formation of concentrated heat areas in the target 20. Thereby reducing the likelihood of crack and nodule formation in or on target 20.

Another embodiment of this invention is comprised of a method of fabricating a rotatable sputter target assembly 10 comprising the steps of: providing a cylindrical target 20, a cylindrical backing tube 40, and a backing material 60; the cylindrical backing 40 tube further comprising an outer surface 41 and the cylindrical target 20 further comprising an inner surface 22. The method is further comprised of rolling the backing material 60 onto the outer surface 41 of the cylindrical backing tube 40 and fitting the cylindrical target 20 on top of the backing material 60. When assembled, the cylindrical target 20 and the cylindrical backing tube 40 are concentric.

The backing material 60 resiliently connects the cylindrical target 20 and the cylindrical backing tube 40 along a multitude of support locations on the inner surface 22 of the target 20. In one embodiment, the backing material 60 is corrugated sheet metal. In another embodiment, the backing material 60 is mesh metal.

In one embodiment, the cylindrical target 20 is comprised of a ceramic or metal oxide material. In another embodiment, the cylindrical target 20 is comprised of at least one of indium tin oxide (TTO) or aluminum zinc oxide (AZO). In some embodiments, the cylindrical backing tube 40 is comprised of at least one of Al, Al alloy, stainless steel, copper, or titanium.

Another embodiment of this invention is comprised of another method of fabricating a rotatable sputter target assembly 10. In this method, a cylindrical target 20 and a cylindrical backing tube 40 are provided. The cylindrical backing tube 40 further comprises an outer surface 41 and the cylindrical target 20 further comprises an inner surface 22. The cylindrical target 20 and cylindrical backing tube 40 are resiliently connected along a multitude of support locations on the inner surface 22 of the target 20 by a backing material 60, wherein the cylindrical target 20 and the cylindrical backing tube 40 are concentric.

In one embodiment, the backing material 60 is corrugated sheet metal. In another embodiment, the backing material 60 is mesh metal.

While this invention has been described in conjunction with the specific embodiments described above, it is evident that many alternatives, combinations, modifications and variations are apparent to those skilled in the art. Accordingly, the preferred embodiments of this invention, as set forth above are intended to be illustrative only, and not in a limiting sense. Various changes can be made without departing from the spirit and scope of this invention. Therefore, the technical scope of the present invention encompasses not only those embodiments described above, but also all that fall within the scope of the appended claims.

This written description uses examples to disclose the invention, including the best mode, and also to enable any person skilled in the art to practice the invention, including making and using any devices or systems and performing any incorporated processes. The patentable scope of the invention is defined by the claims, and may include other examples that occur to those skilled in the art. These other examples are intended to be within the scope of the claims if they have structural elements that do not differ from the literal language of the claims, or if they include equivalent structural elements with insubstantial differences from the literal language of the claims.

What is claimed is:

1. A rotatable sputter target assembly comprising:
a cylindrical target concentrically mounted over a cylindrical backing tube, said cylindrical target having an inner surface and said cylindrical backing tube having an outer surface, and
a backing material located between said cylindrical target and said cylindrical backing tube.

2. The sputter target assembly of claim 1, wherein said backing material resiliently connects said cylindrical target and said cylindrical backing tube along a multitude of support locations on said inner surface of said target.

3. The sputter target assembly of claim 2, wherein said backing material is corrugated sheet metal or mesh metal.

4. The sputter target assembly of clam 3, wherein said cylindrical target is comprised of a ceramic or metal oxide material.

5. The sputter target assembly of clam 4, wherein said cylindrical target is comprised of at least one of indium tin oxide (TTO) or aluminum zinc oxide (AZO).

6. The sputter target assembly of claim 3, wherein said cylindrical backing tube is comprised of at least one of Al, Al alloy, stainless steel, copper, or titanium.

7. The sputter target assembly of claim 3, wherein a mechanical fastener connects said backing material to said cylindrical target and said cylindrical backing tube.

8. The sputter target assembly of claim 3, wherein a chemical fastener connects said backing material to said cylindrical target and said cylindrical backing tube.

9. The sputter target assembly of claim 3, wherein said backing material is secured to said cylindrical target and said cylindrical backing tube by friction.

10. The sputter target assembly of claim 3, wherein said corrugated sheet metal is comprised of inner ridges and outer ridges; said outer ridges contact the inner surface of said cylindrical target and said inner ridges contact the outer surface of said cylindrical backing tube.

11. The sputter target assembly of claim 3, wherein said mesh metal is comprised of outer wire and inner wire; said outer wire contacts the inner surface of said cylindrical target and the inner wire contacts the outer surface of said cylindrical backing tube.

12. A method of fabricating a rotatable sputter target assembly comprising the steps of:
providing a cylindrical target, a cylindrical backing tube, and a backing material; said cylindrical backing tube further comprising an outer surface and said cylindrical target further comprising an inner surface;
rolling said backing material onto the outer surface of said cylindrical backing tube; and
fitting said cylindrical target on top of said backing material, wherein said cylindrical target and said cylindrical backing tube are concentric.

13. The method of claim 12, wherein said backing material resiliently connects said cylindrical target and said cylindrical backing tube along a multitude of support locations on said inner surface of said target.

14. The method of clam 13, wherein said backing material is corrugated sheet metal or mesh metal.

15. The method of clam 13, wherein said cylindrical target is comprised of a ceramic or metal oxide material.

16. The method of clam 14, wherein said cylindrical target is comprised of at least one of indium tin oxide (ITO) or aluminum zinc oxide (AZO).

17. The method of claim 13, wherein said cylindrical backing tube is comprised of at least one of Al, Al alloy, stainless steel, copper, or titanium.

18. A method of fabricating a rotatable sputter target assembly comprising the steps of:
providing a cylindrical target and a cylindrical backing tube; said cylindrical backing tube further comprising an outer surface and said cylindrical target further comprising an inner surface; and
resiliently connecting said cylindrical target and said cylindrical backing tube along a multitude of support locations on said inner surface of said target, wherein said cylindrical target and said cylindrical backing tube are concentric.

19. The method of claim 18, wherein a backing material resiliently connects said cylindrical target and said cylindrical backing tube along a multitude of support locations on said inner surface of said target.

20. The method of clam 18, wherein said backing material is corrugated sheet metal or mesh metal.
